(19) United States
(12) Patent Application Publication
(10) Pub. No.: US 2018/0149061 A1
(43) Pub. Date: May 31, 2018

(54) Thermoelectric Generator for Converting Heat of a Hot Gas Flow Into Electric Energy

(71) Applicant: Bombardier Transportation GmbH, Berlin (DE)

(72) Inventors: Georg Barthelmes, Rheinfelden (DE); Karlheinz Geradts, Staufen AG (CH); Samuel Bucher, Bern (CH)

(21) Appl. No.: 15/579,465

(22) PCT Filed: Jun. 3, 2016
(86) PCT No.: PCT/EP2016/062689

§ 371 Date: Dec. 4, 2017

(30) Foreign Application Priority Data
Jun. 5, 2015 (DE) 10 2015 210 398.6

(51) Int. Cl. F01N 5/02; B61C 5/04; H01L 35/32; H01L 35/34

(52) U.S. Cl. CPC F01N 5/025; B61C 5/04; F02G 5/02; H01L 35/34; H01L 35/32

(57) ABSTRACT

A thermoelectric generator for converting heat of a hot gas flow into electric energy can include at least one thermoelectric module with a plurality of thermoelectric elements. A gas channel on a high-temperature side of the thermoelectric module can conduct the hot gas flow in a flow direction of the gas channel. A heat sink can cool the thermoelectric module and be in contact with the thermoelectric module on a low-temperature side thereof. At least one heat conducting body can extend into the gas channel in a direction running transversely to the flow direction on the high-temperature side of the thermoelectric module and can have a free end within the gas channel. The heat conducting body can be part of the thermoelectric module or connected thereto on the high-temperature side. The thermoelectric generator can have a seal which separates an area between the heat sink and the gas channel from the gas channel and seals the area from the hot gas flow.

The invention relates to a thermoelectric generator for converting heat of a hot gas flow into electric energy, a rail vehicle comprising a thermoelectric generator of this kind, and a method for producing a thermoelectric generator of this kind.

For example, DE 10 2009 058 550 A1 discloses the use of a thermoelectric generator in an exhaust gas line of a combustion engine. In this way, heat of the exhaust gas flow can be converted into electric energy. A thermoelectric module of the generator having a plurality of thermoelectric elements connected in series, which are arranged between a high-temperature side and a low-temperature side, is disposed in each case between a module housing plate on the high-temperature side and the low-temperature side. The module housing plates are part of a module housing which completely surrounds the thermoelectric elements and a flexible compensating element. Damage and soiling of the thermoelectric elements are to be prevented by the completely encapsulated module thus created.

WO 2011/107282 A1 describes a device for utilising exhaust gas heat in combustion engines of motor vehicles. A housing through which exhaust gas passes has an inlet and an outlet for an exhaust gas flow. A plurality of thermoelectric modules are mounted heat-conductively on the housing. The modules extend through openings of a pipe portion and thus protrude both into a flow channel of the housing and into a cooling gas flow outside the housing. Heat conducting fins can be provided to improve the thermal coupling of the thermoelectric modules.

The invention is not limited to the use of a thermoelectric generator in an exhaust gas line of a combustion engine, for example of a diesel engine of a railway locomotive. Rather, the hot gas flow can also be a gas flow other than an exhaust gas flow, for example in an industrial production and/or processing facility or a thermal power plant (for example a CHP unit). In particular, it is also possible that the hot gas flow is coupled via a heat exchanger to an exhaust gas flow, for example of a combustion engine, or to another heat flow, and therefore the heat from the heat flow is transferred via the heat exchanger into the hot gas flow, which flows along the high-temperature side of the thermoelectric generator. In this variant the hot gas flow would function as a heat transfer medium between, for example, the exhaust gas flow or generally a hot heat source and the high-temperature side of the thermoelectric generator.

A problem for thermoelectric generators is the thermal expansion and thermal contraction during the course of the thermal cycles, these being caused by load changes of the combustion engine or generally of the hot heat source and starting in each case with the heating of the thermoelectric generator at start-up and ending with the cooling of the thermoelectric generator at the end of the operation. The device described in WO 2011/107282 A1 for exhaust gas heat utilisation, due to the accommodation of the thermoelectric modules in openings of the housing wall, indeed allows a constraint-free thermal expansion in the direction of the temperature gradient which runs from the outside of the housing into the housing interior. However, thermally induced constraints of the thermoelectric modules occur transversely to the direction of the temperature gradient.

A further problem is the efficiency of the conversion of heat into electric energy. Besides the choice of the materials for the thermoelectric elements, the effective temperature difference is of importance. The efficiency is great when the temperature difference between the high-temperature side and the low-temperature side of the thermoelectric module is great. During operation, only some of the heat on the high-temperature side is converted into electric energy. Another portion of the heat heats the thermoelectric module not only on the high-temperature side, but also on the low-temperature side, even if only to a smaller extent. For this reason, the housing of the device from WO 2011/107282 A1 is cooled on its outside.

In spite of the cooling, a temperature difference is produced for example in stationary conditions with constant hot gas flow and constant cooling fluid flow in the thermoelectric module, which temperature difference is much smaller than the temperature difference between the hot gas flow and cooling fluid flow. The distance between the contact of the material pair on the high-temperature side and the contact of the material pair on the low-temperature side is often only a few millimetres in practice.

In addition to the usable heat flow on the high-temperature side of the thermoelectric module, some of which can be converted into electric power, parasitic heat flows are produced between the high-temperature side and the low-temperature side and flow past the thermoelectric module. These parasitic heat flows are transferred on the one hand via the gas space in the environment of the thermoelectric modules by heat conduction, convection and heat radiation, and on the other hand via solid body heat bridges between high-temperature side and low-temperature side. These solid body heat bridges, in thermoelectric generators other than those described in WO 2011/107282 A1, are formed for example by supporting structures intended to keep the mechanical loading of the thermoelectric modules low.

Yet another problem of the use of thermoelectric modules having a plurality of thermoelectric elements, in particular connected in series, is the sensitivity of the thermoelectric modules with respect to components of the hot gas flow. The use of semiconductor materials for the thermoelectric elements is usual. However, carriers, in particular board-like carriers, of the thermoelectric elements can be sensitive with respect to components of the hot gas flow. This is the case for example if surface regions of the thermoelectric module are copper-plated. In particular, particles in the exhaust gas flow, but also other components, such as sulphur, can damage the surfaces of the thermoelectric module by chemical reactions.

One object of the present invention is to describe a thermoelectric generator for converting heat of a hot gas flow into electric energy, which thermoelectric generator enables a conversion of the heat in the hot gas flow into electric energy with high efficiency, enables a high number of thermal cycles without damage or destruction of thermoelectric modules by mechanical constraints, and protects thermoelectric elements and/or modules against components of the hot gas flow. A further object is to describe a rail vehicle comprising a thermoelectric generator of this kind, and a method for producing a thermoelectric generator of this kind.

In accordance with a basic concept of the present invention, a heat exchanger is used which transfers heat from the hot gas flow to the particular thermoelectric module. An example of a heat exchanger of this kind is the heat conducting fin mentioned in WO 2011/107282 A1, which extends from the thermoelectric module into the hot gas flow. Generally, a part (heat conducting body) made of solid material which in particular has the greatest possible coefficient of heat conduction is preferred as heat exchanger. An example of such a material is aluminium.

In addition, a seal is used which can also be referred to as an area divider. This seal separates the area through which the hot gas flow flows from an area disposed between the area for the hot gas flow and the low-temperature side of the particular thermoelectric module. This separated area contains a portion of the at least one heat exchanger, but also gas and/or a heat-insulating material. Both in the case of gas and of heat-insulating material, the hot gas in the gas flow is prevented from coming directly into contact with the low-temperature side of the thermoelectric module. The seal therefore prevents this contact. In the case of a heat-insulating material, the surface thereof facing the hot gas flow can be referred to as a seal. In the case that the area separated off by the seal contains gas, in particular exclusively gas, and contains a portion of the heat exchanger, the seal can be planar or layer-like or sheet-like for example, that is to say the dimension of the seal in the direction in which the heat exchanger transfers the heat from the hot gas flow to the thermoelectric module is smaller than the dimensions of the seal in the directions transverse to the direction of heat exchange of the heat exchanger. In this case, the seal can also be said to be wall-like, since it separates the area for the hot gas flow from the area with gas.

The seal can be made for example of a closed or of a porous material. If the seal is made of porous material or comprises porous material, it is then preferred that the flow resistance of a flow of gas through the seal is much greater than the flow resistance of the hot gas flow.

The seal is preferably made of a flexible material. This means that mechanical forces acting thereon lead to a deformation of the seal. Merely small and preferably negligible forces are therefore transferred to the thermoelectric module via the seal, and the thermoelectric module together with the heat exchanger can expand and contract in a constraint-free manner during the above-mentioned thermal cycles.

A nonwoven or woven material formed of fibres is particularly preferred as material of the seal, wherein the nonwoven or woven material is optionally combined with at least one further, preferably likewise flexible material, for example a coating of the individual fibres and/or of the nonwoven or woven material. Due to their temperature resistance even at high gas flow temperatures up to some 100° C. or above, mineral fibres, in particular synthetic mineral fibres, are well suited for producing the nonwoven or woven material.

In particular, the seal can be passed through at least at one point by the heat conducting body or one of the heat conducting bodies or by the thermoelectric module. Alternatively or additionally, parts of the seal are separated from one another at least at one point by the heat conducting body or one of the heat conducting bodies or by the thermoelectric module, that is to say the different parts of the seal extend on mutually opposed sides of the heat conducting body or thermoelectric module, wherein the connection of the mutually opposed sides runs along the flow direction of the hot gas flow. In particular, it is possible in this way that a plurality or multiplicity of heat conducting bodies or of protrusions of at least one heat conducting body extends through the seal and/or between different parts of the seal, more specifically in a direction running from the low-temperature side of the thermoelectric module into the hot gas flow, transversely to the flow direction thereof, or vice versa. During operation of the thermoelectric generator, a heat flow can therefore take place through the heat conducting body to the thermoelectric elements, whereas the seal on different sides of the heat conducting body separates the area for the hot gas flow from the area between seal and low-temperature side of the thermoelectric module.

The at least one heat conducting body has a free end within the area for the hot gas flow, and the hot gas flow can flow around said free end on all sides with the exception of the side in the direction of the extent of the heat conducting body to the low-temperature side of the thermoelectric module, and the hot gas also flows around said free end during operation. In particular, protrusions formed by the heat conducting body or by a plurality of the heat conducting bodies can therefore extend into the gas channel forming the area for the flow of the hot gas. For example, the protrusions can be formed as fins of a heat exchanger for transferring the heat of the hot gas flow to the thermoelectric module. For example, it is thus possible that a one-part heat conducting body forms a plurality of protrusions and in particular a plurality of fin-like protrusions. Alternatively or additionally, different heat conducting bodies can each form at least one protrusion, in particular a fin-like protrusion.

The free end is not in contact with other solid bodies. Thus, no mechanical forces are exerted onto the free end and the heat conducting body by thermal expansion and contraction, and therefore no constraints of the thermoelectric module occur.

Depending on the type of heat conducting body, but also depending on the materials of the thermoelectric module, in particular depending on the heat conductivity and any need for protection against harmful components of the hot gas flow, the seal can be positioned at different positions in the direction of the heat conduction through the heat conducting body. For example, the seal can be positioned on a portion of a protrusion formed by the heat conducting body, so that the protrusion passes through the seal and/or separates different parts of the seal from one another. However, it is also possible that the seal is positioned in the region of the fixed end of the heat conducting body, that is to say in the region in which the different materials of the thermoelectric elements of the thermoelectric module are in contact with one another on the high-temperature side of said thermoelectric module. It is additionally possible that the seal is arranged in a position between the contact region of the material pair on the high-temperature side and the contact region of the material pair of the thermoelectric generator on the low-temperature side. In this case, the contact region of the material pair of the thermoelectric module lies in the area through which the hot gas flows.

Put more generally, however, it is preferred that in the case of thermoelectric elements which each have a pair of different materials which are in contact with one another in a first contact region on the low-temperature side and are in contact with one another in a second contact region on the high-temperature side, so that an electrical voltage is produced between the first and the second contact region on account of a higher temperature in the second contact region than in the first contact region, the first contact region is disposed in the area separated by the seal from the gas channel. It is also preferred that the second contact region is likewise disposed in the area separated by the seal from the gas channel. However, the seal is preferably disposed close to the second contact region. In particular, the distance of the second contact region from the seal in the direction of the extent of the heat conducting body to the free end thereof in the gas channel is preferably at most a tenth and in particular at most a twentieth of the length of the heat conducting body from the position of the seal to the free end in the gas channel or, in another case, of the length of the end region of the thermoelectric module starting from the position of the seal plus the length of the heat conducting body to the free end thereof in the aforementioned direction in which the heat transport takes place.

It has already been mentioned that the seal can extend between different protrusions of the heat conducting body or a plurality of the heat conducting bodies, or that parts of the seal can extend therebetween. In this case, but also in other cases, the seal can extend from the heat conducting bodies or from one of the heat conducting bodies to a gas channel wall or to a supporting part of the thermoelectric generator, for example to a housing part of the thermoelectric generator. A supporting part is understood to mean a part of the generator which has any kind of supporting function. This can be the function of supporting the thermoelectric module and/or supporting another part of the thermoelectric generator. In particular, the supporting part can be connected to a heat sink for cooling the thermoelectric module. Although the seal extends to the supporting part, it is preferably not fixedly connected to the supporting part. This prevents the constraint, that is to say the transfer of mechanical forces from the supporting part to the thermoelectric module or vice versa to a significant extent.

With regard to the invention, it is preferred to use a cooling medium with high heat capacity to transport heat away from the heat sink, in other words liquids such as water are preferred compared to gases.

The area separated by the seal from the gas channel can optionally comprise an inlet and an outlet separately from the gas channel, through which inlet and outlet a flushing fluid (preferably a flushing gas) for flushing the area can be admitted and discharged during and/or after operation of the thermoelectric generator. A separate inlet and outlet are understood to mean that the flushing fluid can be admitted into and discharged from the area without flowing through the gas channel. This makes it possible to clean the area, in particular of residues or parts that pass or have passed from the gas channel into the area on account of a leak of the seal. In particular if soot particles also pass through the gas channel during operation, flushing in particular during operation of the thermoelectric generator, but also beforehand and/or thereafter, is advantageous. If the flushing fluid flows through the separated area during operation, said fluid can be for example a gas (for example air), which flows through the area at a higher pressure than the pressure of the gas in the hot gas flow. This prevents a portion of the hot gas flow from passing into the flushed area, since the pressure in the flushed area is higher.

In accordance with a further fundamental concept of the invention, the thermoelectric generator has a heat sink which serves to cool the thermoelectric module. In particular, a cooling fluid, preferably a cooling liquid, flows through the heat sink, so that an effective cooling of the heat sink and therefore of the thermoelectric module takes place. The heat sink is in contact with the thermoelectric module on a low-temperature side of the thermoelectric module. Of course, the thermoelectric generator can have a plurality of thermoelectric modules, which are in contact with the same heat sink and/or on the low-temperature side thereof are in contact with separate, different heat sinks.

In particular, the following is proposed: a thermoelectric generator for converting heat of a hot gas flow into electric energy, wherein the thermoelectric generator comprises:
at least one thermoelectric module with a plurality of thermoelectric elements,
a gas channel on a high-temperature side of the thermoelectric module for conducting the hot gas flow in a flow direction of the gas channel,
a heat sink for cooling the thermoelectric module, wherein the heat sink is in contact with the thermoelectric module on a low-temperature side of the thermoelectric module, and
at least one heat conducting body which extends into the gas channel in a direction running transversely to the flow direction on the high-temperature side of the thermoelectric module and which has a free end within the gas channel, wherein the heat conducting body is part of the thermoelectric module or is connected to the thermoelectric module on the high-temperature side of the thermoelectric module,
   wherein the thermoelectric generator has a seal which separates an area arranged between the heat sink and the gas channel from the gas channel and seals the area from the hot gas flow flowing in the gas channel during the operation of the thermoelectric generator.

Furthermore, the scope of the invention includes a rail vehicle comprising a thermoelectric generator in one of the embodiments of the thermoelectric generator disclosed in this description, the claims, and the drawing, wherein the rail vehicle has a combustion engine and the thermoelectric generator is arranged in an exhaust gas tract of the engine or is thermally coupled to the exhaust gas tract.

The following is additionally proposed: a method for producing a thermoelectric generator for converting heat of a hot gas flow into electric energy, comprising the following steps:
providing at least one thermoelectric module having a plurality of thermoelectric elements,
providing a gas channel for guiding the hot gas flow in a flow direction of the gas channel on a high-temperature side of the thermoelectric module,
arranging a heat sink for cooling the thermoelectric module on a low-temperature side of the thermoelectric module,
coupling the heat sink to the thermoelectric module on the low-temperature side, and
arranging at least one heat conducting body on the high-temperature side of the thermoelectric module, so that the heat conducting body extends into the gas channel in a direction transverse to the flow direction and has a free end within the gas channel, wherein the heat conducting body is part of the thermoelectric module or is connected to the thermoelectric module on the high-temperature side of the thermoelectric module,
   wherein a seal is arranged so that it separates an area arranged between the heat sink and the gas channel from the gas channel and, during operation of the thermoelectric generator, seals the area with respect to the hot gas flow flowing in the gas channel.

In practice, the seal does not completely seal the area with respect to the gas channel, as is generally also not the case with any type of seals. For example at contact points between the seal and the heat conducting body and/or the thermoelectric module, a passage of hot gas into the area can be possible. In any case, however, the seal causes a separation between the area and the gas channel hindering or even almost completely preventing entry of hot gas into the area.

It is preferred that the heat sink supports the thermoelectric module. It is therefore possible to dispense with supporting structures and thus solid body heat bridges between the high-temperature side and low-temperature side of the thermoelectric modules, so that the parasitic heat flows remain small and the temperature difference over the thermoelectric modules is as close as possible to the temperature difference between a hot gas flow and cooling fluid.

In particular in vehicles, for example rail vehicles, the space available for combustion engines and in the underfloor region is already well utilised. There is thus no, or little additional space available for the thermoelectric generator. This is also the case for any additional exhaust gas heat exchangers for transferring exhaust gas heat to a separate hot gas flow from the exhaust gas heat exchanger to the thermoelectric generator, and/or a separate cooling for cooling the thermoelectric generator. The same is true for additional weight, which shall be as low as possible. For this reason alone, systems without additional circuits for the hot gas flow are preferred in vehicles.

In particular for the use in vehicles, but also generally, it is therefore preferred to well utilise the installation space for the thermoelectric generator by providing or using a plurality of heat conducting bodies which extend from different sides of the gas channel for the hot gas flow into the gas channel and have a free end there. For example, a first group of a plurality of heat conducting bodies or protrusions can extend in the manner of a comb into the gas channel from one side thereof and a second group of heat conducting bodies or protrusions can extend in the manner of a second comb from another side into the gas channel, so that individual protrusions of the first comb extend into gaps between protrusions of the second comb and vice versa. The protrusions of the different combs are interlaced with one another.

In particular, the two combs can extend into the gas channel from opposite sides, so that free ends of protrusions of the first comb are disposed between protrusions of the second comb, and vice versa. In particular, the protrusions of the first comb and of the second comb form walls of flow channels for the hot gas flow, i.e. these flow channels jointly and optionally with additional flow channels form the overall cross-section available for the flow of hot gas. Transversely to the flow direction along the opposite sides from which the protrusions of the two combs extend into the gas channel, the protrusions of the first comb and the protrusions of the second comb follow one another in alternation. In all cases, however, it is preferred that the protrusions of the first comb and the protrusions of the second comb do not contact one another.

Not only in the case of the previously described comb-like groups of protrusions, but generally in the case of a plurality of protrusions which extend into the interior of the gas channel and supply heat to at least one thermoelectric module, it is preferred that the plurality of the protrusions form flow channels in particular as already described or in another way, which flow channels jointly contribute to the overall flow cross-section of the gas channel. The individual flow channels therefore have a smaller flow cross-section than the overall gas channel. This leads to a sound-damping property, so that the thermoelectric generator can be used in particular as an exhaust gas sound damper in the exhaust gas flow of a combustion engine. This in turn makes it possible to replace an existing exhaust gas sound damper or an exhaust gas sound damper also existing in systems of the same type by the thermoelectric generator. There is thus no need for any additional installation space, or only little additional installation space is required. The same is true for the additional weight.

Regardless of the possibility to form the plurality of individual flow channels, it is preferred that the thermoelectric generator comprises an arbitrary combination of the following features:
A plurality of thermoelectric modules (for example strip-like modules or block-like modules), which each have a plurality of thermoelectric elements, are thermally coupled via heat conducting bodies to the gas channel, preferably to an exhaust gas channel without intermediate circuit.
The thermoelectric generator is constructed in a modular manner from basic units.
Each of the basic units can comprise a heat sink, at least one thermoelectric module which is coupled on its low-temperature side to the heat sink, at least one heat conducting body with protrusions which protrude in their extent as far as their free ends into the gas channel, the seal according to the invention, and optionally at least one connection between the heat sink and the particular thermoelectric module. This connection provides a good thermal coupling of the thermoelectric module to the heat sink. Examples will be described in greater detail. As a result of this modular structure, thermoelectric generators having different numbers of basic units can be produced in accordance with different anticipated heat flows.
A plurality of basic units can be arranged adjacently in a direction transverse to the flow direction of the hot gas. In particular, as already described, basic units can preferably be arranged on mutually opposed sides of the gas channel, that is to say at least one thermoelectric module is disposed on the opposite sides of the gas channel, with heat conducting bodies or protrusions extending into the interior of the gas channel from said thermoelectric modules. In particular at the end of a modular assembly consisting of a plurality of basic units, there can be also just one basic unit, that is to say heat conducting bodies and/or protrusions protrude into the interior of a gas channel merely from one side or pass through the gas channel as far as approximately the opposite side. An example will be described further below.
In particular, the heat sink of the basic unit forms the supporting part supporting the at least one thermoelectric module coupled thereto. The heat sink is therefore mechanically coupled, i.e. connected, to a supporting part of the thermoelectric generator. The thermoelectric module is connected merely indirectly via the heat sink to the supporting part of the thermoelectric generator. This makes it possible to arrange the thermoelectric modules in a constraint-free manner. The supporting part of the thermoelectric generator is in one exemplary embodiment a supporting frame, for example a supporting frame arranged beneath. A further supporting frame, for example a supporting frame arranged above, can be provided, but does not support the heat sink, and instead is part of a housing of the thermoelectric generator.
When the aforementioned connection between the heat sink and the at least one thermoelectric module is present or provided, the connection can consist of, or comprise at least one heat conducting body, for example a fin-like heat conducting body, wherein this heat conducting body extends from the heat sink to the thermoelectric module and is arranged on the low-temperature side thereof. A connection of this type can be for example an integral part of the heat sink, that is to say there is no need for a further mechanical transition from the heat sink to the connection. Alternatively, however, the connection can be formed as a separate connection element. In particular in the case of strip-like thermoelectric modules, a connection can be provided between each module and the heat sink. Here, at least one of the connections in particular can connect the heat sink not only to a thermoelectric module, but to a plurality of thermoelectric modules, for example to two thermoelectric modules.
The heat conducting body or the heat conducting bodies supplying the particular thermoelectric module during operation with heat from the hot gas flow can be an integral part of the thermoelectric module, can be mechanically and therefore also thermally coupled to the particular thermoelectric module, or an additional connection can be provided, for example an additional connection element which mechanically and thus thermally connects the thermoelectric module to the heat conducting body. In the case of the strip-like thermoelectric modules, as described similarly for the low-temperature side, a connection of the heat conducting body or directly the heat conducting body itself on the high-temperature side can be connected to a plurality of the thermoelectric modules, for example to two thermoelectric modules on opposite sides of the connection or of the heat conducting body.
In particular as already described above, comb-like groups of protrusions can be arranged on opposite sides of a gas channel, wherein the protrusions of the different comb-like groups extend into the interior of the same gas channel. In the case of the basic units, a basic unit with at least one thermoelectric module is thus disposed on each of the opposite sides of the gas channel. The gas channel is delimited on each of the sides by a preferably flexible seal with respect to an area disposed between the gas channel and the low-temperature side of the particular thermoelectric module. If the protrusions of the mutually opposed basic units do not contact one another, a constraint-free thermal expansion and contraction is possible. For example, the protrusions can be fin-like and can be interlaced with one another in the manner mentioned further above. Installation space is saved in this way, and the surface of the heat conducting bodies as a whole per volume is increased, so that the heat transfer from the hot gas flow to the thermoelectric modules is improved on the whole.
Optionally, with use of the basic units, but also generally with a multiplicity of protrusions extending into the gas channel, the length of the protrusions over which the protrusions extend into the gas channel to their free end can vary. In particular, this length can increase in the flow direction of the hot gas in order to increase the surface of the heat conducting bodies in the flow direction of the hot gas. The decrease of the temperature of the hot gas in the flow direction is thus compensated at least in part, and a heat flow through the heat conducting bodies of the same magnitude is produced approximately at different positions in the flow direction. In particular, a first basic unit can comprise heat conducting bodies of a first length, which is constant within the basic unit, and a second basic unit can comprise heat conducting bodies of a second length, which is constant within the basic unit. The first basic unit is arranged in front of the second basic unit in flow direction. However, it is also possible alternatively to vary the length of the heat conducting bodies within a basic unit so that it increases in the flow direction.
The material of the seal can comprise for example slot-like recesses or slot-like through-openings for the heat conducting bodies not only in respect of the basic units. Cuts for producing such recesses or openings can be produced for example using mechanical tools and/or by means of water jet cutting.
The seal can be produced from a compressible material not only in the case of the basic units.
Alternatively to recesses or through-openings in the material of the seal, not only in the case of the basic units, but also generally, parts of the seal can be flexible strip-like parts, for example bent films (for example made of metal, ceramic or temperature-resistant polymers), fibre bundles (for example cables) produced from fibres and/or hollow bodies made of rubber and/or polymer. In all these cases it should be ensured that the used starting material is temperature-resistant, i.e. permanently withstands the temperature of the hot gas flow.
Not only with regard to the above-mentioned possibility of flushing the area separated by the seal with respect to the gas channel, the flushing can be used, alternatively or additionally for the purpose of cleaning, for a cooling of the area. In this case, an additional cooling of the area separated by the seal is achieved by means of the flushing fluid (preferably the flushing gas), in particular with flushing air, which takes place additionally to the cooling of the heat sink. The temperature difference of the contact regions of the material pairs of the thermoelectric module between hot-temperature side and low-temperature side can therefore be greater during operation of the thermoelectric generator. In particular, the seal in this case runs at a position between the contact regions of the material pair on the hot-temperature side and the contact regions of the material pair on the low-temperature side. Substantially merely the contact region on the low-temperature side is therefore cooled by the flushing fluid.
The basic units can be arranged in succession in the flow direction of the hot gas not only in the case of a changing length of the heat conducting bodies. Optionally, at least one supporting structure can be provided in at least one transition region, in which two basic units arranged in succession in the flow direction are adjacent to one another, which supporting structure is disposed in particular outside the flow channel or the flow channels for the hot gas. In particular, the supporting structure can run in a closed manner around the overall flow cross-section for the hot gas flow. This makes it possible in particular for the basic units to be supported or secured to the supporting structure and/or with respect to one another and therefore to be mechanically stabilised. In addition, the supporting structure can optionally support seals between the gas channel and the separated area.
The basic units and in particular the different basic units arranged in succession in the flow direction are connected in the flow direction preferably merely on one side (for example merely in the flow direction at the start of the thermoelectric generator or at the end of the thermoelectric generator) to a supporting structure of the generator, which for example can be a supporting frame. This enables the constraint-free thermal expansion and contraction. Optionally, a guide can be disposed in the flow direction at a distance from the fastening of the basic units to the supporting structure, or can extend in the flow direction, wherein the guide enables a thermal expansion and contraction of the arrangement of the basic units. A relative movement between at least one basic unit and the guide is therefore possible, that is to say the guide is not fixedly connected to any of the basic units supported by the supporting structure. The guide is disposed in particular laterally, that is to say outside the edge of the gas channel or the gas channels. A plurality of guides of this kind can also be provided.
In particular with use of strip-like thermoelectric modules, the thermoelectric modules can be arranged adjacently in a direction transverse to the flow direction of the hot gas. Here, they form a stack of strip-like modules, wherein the strip-like modules are each distanced from one another in pairs. In this case, additional planar termination elements can be provided, for example termination sheets, which, at least on one side of the stack, form the last element of the stack in the sequence of the strip-like modules. The termination elements therefore laterally delimit the area available partially for the flow of hot gas, and thus form the edge of this area. A plurality of planar termination elements of this kind can be displaceable relative to one another so as to avoid, or keep low, mechanical constraints as a result of thermal expansion and contraction. The termination elements can be supported in particular by the aforementioned supporting structure or can be supported at least temporarily depending on the state of the thermal expansion or contraction. A second supporting structure can optionally be provided, which is distanced relative to the first supporting structure in the flow direction and is mounted movably, and in particular is guided movably, relative to the first supporting structure in the flow direction. This also avoids thermal constraints.
Alternatively or additionally to the guidance in the flow direction, the heat sinks of the basic units can be connected to one another by planar supporting structures perpendicularly to the flow direction, in each case between two levels of heat sinks following from one another in the flow direction so as to produce a stabilisation of the thermoelectric generator transversely to the flow direction. These supporting structures preferably have recesses for the flow channels of the hot gas and, if provided, of the flushing gas. In addition, these supporting structures can be used to support the seal between the hot gas channel and the area through which no hot gas passes, in or against the flow direction.

The hydraulic connection of a plurality of cooling channels of the heat sink or of the heat sinks is well known to a person skilled in the art and will not be described here in greater detail. The same is true for the electrical connection of a plurality of thermoelectric modules or basic units. The electrical connections to the thermoelectric modules can be disposed in particular in the area separated by the seal from the gas channel. In this way, the electric connections are protected against particularly high temperatures at the level of the temperature of the hot gas flow.

Instead of the strip-like thermoelectric modules already mentioned above as an example, block-like, in particular cuboid, thermoelectric modules can be used. In particular, these block-like modules on the low-temperature side can comprise a flat surface, enabling a thermal coupling over a large area to the associated heat sink. Alternatively or additionally, at least one block-like thermoelectric module can have a flat surface on the high-temperature side, which flat surface enables a large-area coupling of one or more heat sinks, wherein each heat sink can have a plurality of protrusions, which extend into the gas channel. In this case, the seal is disposed in a position, as viewed from the low-temperature side of the module, on the other side of the high-temperature side of the module, that is to say in the region of the protrusions of the heat sink or heat sinks.

In particular, a plurality of the block-like modules can be thermally coupled to a common heat sink, for example arranged in a rectangular grid.

Alternatively or additionally to the arrangement of a seal between the individual protrusions of the heat conducting body, a seal can be arranged between various arrangements formed of at least one block-like thermoelectric module and a heat conducting body thermally coupled thereto. In this case as well, the seal separates the gas channel from an area between gas channel and low-temperature side of the various block-like thermoelectric modules.

Alternatively to the heat conducting bodies having a plurality of protrusions, which for example can be produced by extrusion or milling, the individual, for example fin-like, heat conducting bodies already mentioned can also be used. In all these cases, protrusions, for example fins, which extend into the gas channel in a comb-like manner from opposite sides thereof, can be interlaced with one another, that is to say the protrusions from one side alternate with protrusions from the other side.

Individual fins can have an L- or T-shaped cross-section in the case of block-like thermoelectric modules, so that in particular a short limb of the L or T is connected on the high-temperature side to the block-like thermoelectric module.

Generally, for all aforementioned connections of parts and also for the connections yet to be described hereinafter, different joining techniques can be used, in particular adhesive bonding, welding, soldering, frictionally engaged joining and/or positively engaged joining.

In the case of block-like thermoelectric modules, thermally induced curvatures may occur at the surfaces, so that in particular the large-area contact with the heat sink and/or the heat conducting body is worsened. In order to solve this problem, it is proposed to arrange flat compensation elements, for example elastic compensation elements, between the heat sink and the module and/or between the module and the heat conducting body.

Depending on the embodiment of the seal, this damps to a greater or lesser extent mechanical vibrations which can be excited, in particular in the case of an exhaust gas flow, in the exhaust gas tract of a combustion engine. In particular, fin-like heat conducting bodies are capable of vibration. Although the seal or the parts of the seal is/are preferably flexible, the forces necessary to deform the seal can nevertheless damp mechanical vibrations. In particular, the stiffness and/or strength of the seal can be matched to the anticipated frequencies of mechanical vibrations in order to damp vibrations at these frequencies particularly well. The same is true for mechanical vibrations which can be excited other than by an exhaust gas flow. For example, vibrations of a combustion engine can be transferred via mechanical contacts on the thermoelectric generator.

The at least one heat sink can be made in particular from a metal, preferably a metal with a high heat conductivity, for example aluminium, an aluminium alloy, a copper alloy, or carbon steel.

The heat sink can be produced from a material block, for example by milling and drilling. The channels for the cooling fluid and the connections can be produced in this way. Alternatively, the heat sink can be produced as an extruded hollow profile. A further variant is the production in a casting method. It is also possible to produce, for example to weld, the heat sink from individual parts, for example profiles, tubes and plates. A further possible production method for the heat sink is additive manufacturing (generally known as “3D printing”). In particular in the case of milled, cast, welded or additively produced heat sinks, the surface pointing towards the low-temperature side of the thermoelectric module can be formed as a flat surface. In particular, the mechanical and thermal connection between heat sink and module can be produced via at least one additional connection element. Alternatively, the heat sink can be produced on the side pointing towards the at least one thermoelectric module with protrusions, for example fin-like protrusions, to which individual thermoelectric modules, in particular strip-like modules, are secured. Block-like and in particular cuboid modules can be secured directly on a planar surface of the heat sink, optionally with compensation elements for compensation of thermal deformation of the planar surface. In particular in the case of a heat sink formed from extruded hollow profiles and in the case of cast, welded or additively manufactured heat sinks, the surface for the connection to the at least one module can be subject to secondary processing (for example material can be removed by machining), before the at least one block-like module is secured to the surface. Surfaces of the material of the heat sink, including inwardly lying surfaces at the edge of cooling liquid channels, can preferably be coated in order to make the material resistant to atmospheric oxygen, the cooling medium and/or components present in the hot gas.

Connection elements for mechanical and thermal connection of heat sink and thermoelectric modules can be produced in particular from the same materials as those mentioned above for the heat sink. The connection element and the heat sink preferably consist of the same material. Connection elements can be punched, sawn or cut from metal sheets and optionally bent or angled into a desired shape (for example with L- or T-profile). Connection elements can be joined to the heat sink for example by soldering, gluing or welding. Mechanical connections between connection elements and thermoelectric modules (in particular module strips) can be produced in particular by soldering or gluing.

As mentioned, thermoelectric modules can be, for example, strip-like or block-like, in particular cuboid. Modules of this kind are commercially available. Details regarding their structure and materials therefore are not described in greater detail in this description. In particular in order to enable soldering, the module can be produced on the low-temperature side and/or on the high-temperature side from a metal. This includes the possibility that the surface is metallised in the connection region to the connection element or heat conducting body. This is true both for strip-like and for block-like modules. Electrical insulation is preferably provided in the contact region between heat conducting body and module and/or between module and heat sink and connection element to the heat sink (alternatively between connection element and heat sink).

For the heat conducting body, which transfers heat from the hot gas flow to the thermoelectric module during operation, the same materials as mentioned above with regard to the heat sink are preferred. In the case of a thermoelectric module strip, the heat conducting bodies can be produced for example as strips of planar material (for example sheet metal strip) or undulating sheet metal strips. Here, the wave troughs in the gas channel extend preferably in the flow direction so as to obtain an increased surface, yet not significantly increase the flow resistance in the gas channel. Thereby, the undulating sheet metal strips, similarly to the straight sheet metal strips, can be arranged opposite one another and interlaced with one another in the gas channel. A plurality of fins or other protrusions protruding into the gas channel can be oriented for example with the aid of templates, moulds or other spacing tools so that a uniform distance is provided therebetween. The individual distance preferably should not deviate by more than 20% from the average distance between two protrusions. The strip-like or fin-like heat conducting bodies can be punched, cut or sawn from larger sheets or from strip-like material, as is already known per se.

In the case of block-like thermoelectric modules, the heat conducting bodies are produced for example by milling or extrusion as fin bodies. As mentioned, heat conducting bodies that are L- or T-shaped in cross-section can be produced alternatively, the short profile limb of which is connected over the greatest area possible to the surface of the block-like module. Alternatively, pin heat sinks can be used as heat conducting bodies, i.e. a plurality of pin-like protrusions extends into the interior of the gas channel. In particular, the heat conducting body can be connected to the module by soldering or gluing. A further possibility lies in producing the module already with protrusions for example in fin form or pin form on the high-temperature side. In this case, the connection of the module to an additional heat conducting body is spared.

A flexible seal, that is to say a seal that deforms under the action of external forces, can be made in particular of material that is already flexible prior to production or that becomes flexible as a result of the production. For example, cavities can be produced during the production of the seal which make the material flexible as a whole. However, a nonwoven material or a mat made of mineral fibres is preferred as seal. For example, a slot-like hole can be cut or punched into the nonwoven material or the mat. The shape of the hole is dependent on the cross-sectional shape of the heat conducting body that passes through or should pass through the seal at the hole. The sealing function between the seal and the heat conducting body is ensured preferably by the friction of the two parts. Without this friction, the seal could move relative to the heat conducting body, and the sealing function could be worsened. A further possibility lies in the fact that free ends of heat conducting bodies extending from an opposite side of the gas channel into the gas channel hold the seal in position, i.e. the seal cannot move further in the direction of the opposite side of the gas channel. Alternatively or additionally, the seal can be held for example by a mount on an edge termination element of the gas channel and/or can be held on a reinforcement structure, and at least the freedom of movement of the seal can be limited in this way. Alternatively or additionally, the seal can be fixedly glued to the heat conducting body. A seal can not only separate the aforementioned area from the gas channel. Rather, at least one seal can also be used to seal the transition between modules, in particular the basic units, arranged in succession in the flow direction. The same materials as for the separating seal can be considered for this purpose. These seals can also be fixedly glued or held in position by clamping forces.

Exemplary embodiments of the invention will now be described with reference to the accompanying drawing. The individual figures of the drawing show:

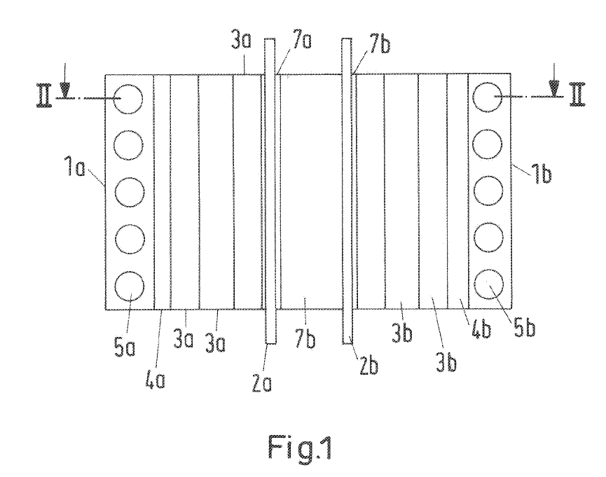

FIG. 1 a longitudinal section through an arrangement having two heat sinks on opposite sides of a gas channel, wherein thermoelectric modules with heat conducting bodies secured thereto extend starting from each of the heat sinks in the direction of the interior of the gas channel,

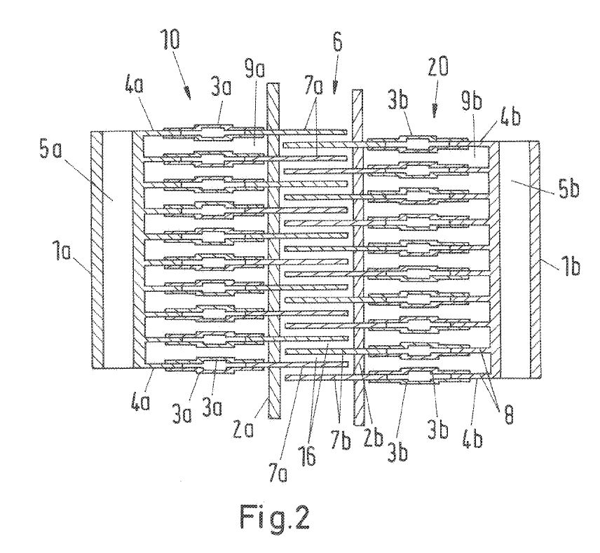

FIG. 2 a cross-section through the arrangement illustrated in FIG. 1 along the line II-II,

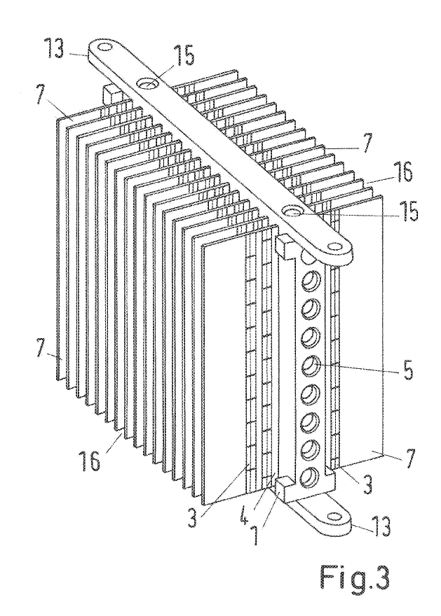

FIG. 3 an isometric three-dimensional illustration of an arrangement with a heat sink, from which thermoelectric modules with heat conducting bodies secured thereto extend on mutually opposed sides,

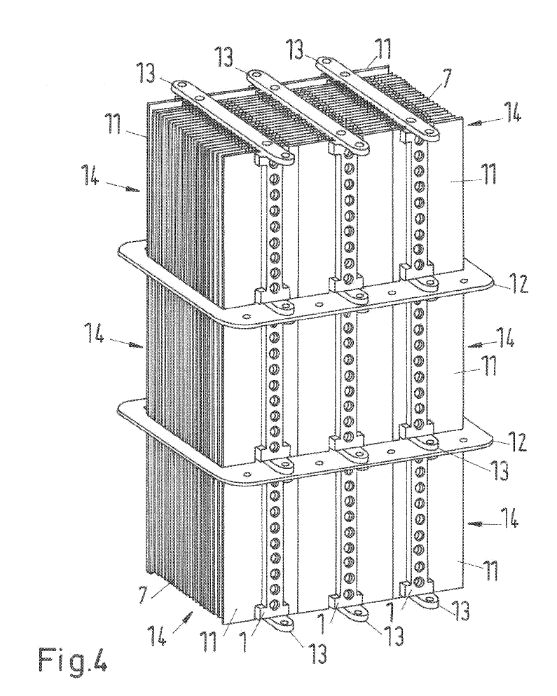

FIG. 4 an isometric three-dimensional illustration of a plurality of the arrangements illustrated in FIG. 3, which are arranged adjacently and in levels one above the other,

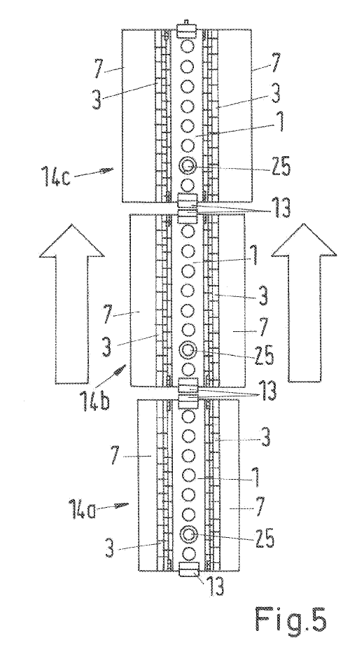

FIG. 5 an illustration of three arrangements similar to the arrangement illustrated in FIG. 3, wherein the three arrangements are arranged in succession in the flow direction of the hot gas and have different lengths transversely to the direction of the gas flow, over which the heat conducting bodies extend into the gas channel,

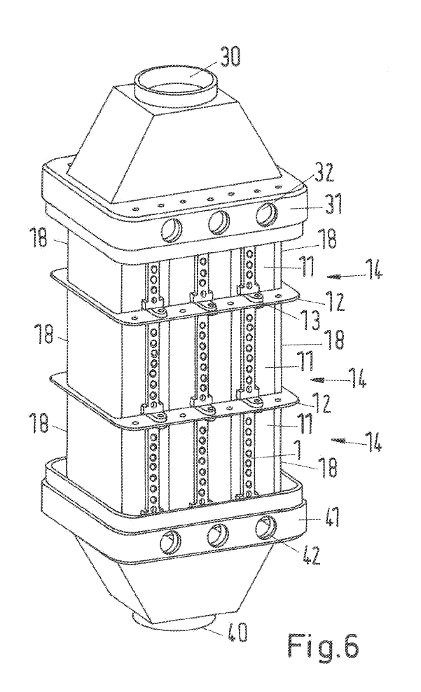

FIG. 6 the arrangement illustrated in FIG. 4 with additional supporting frame, a gas inlet, and a gas outlet,

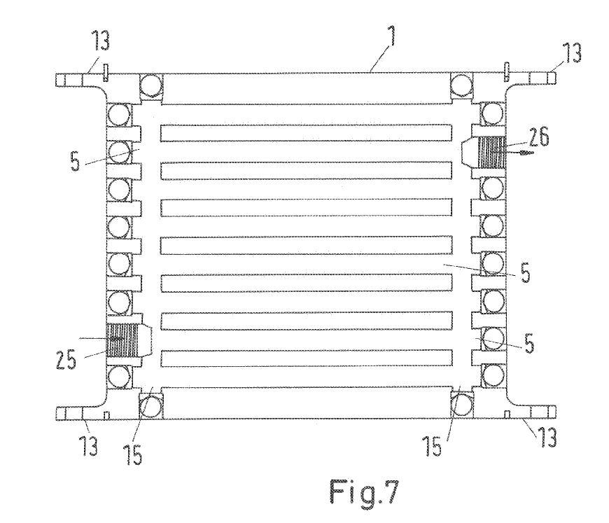

FIG. 7 a cross-section through a heat sink, which for example can be used as a heat sink in one of the arrangements in FIG. 1 to FIG. 6 and FIG. 8 and FIG. 9,

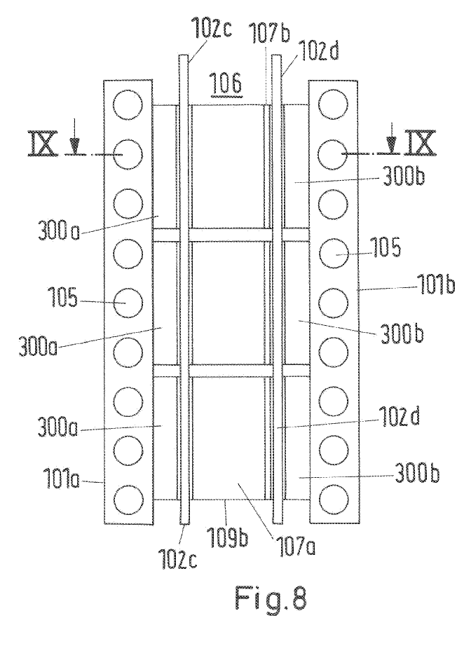

FIG. 8 a longitudinal section similar to the longitudinal section in FIG. 1, but through an arrangement with cuboid thermoelectric modules instead of with strip-like thermoelectric modules,

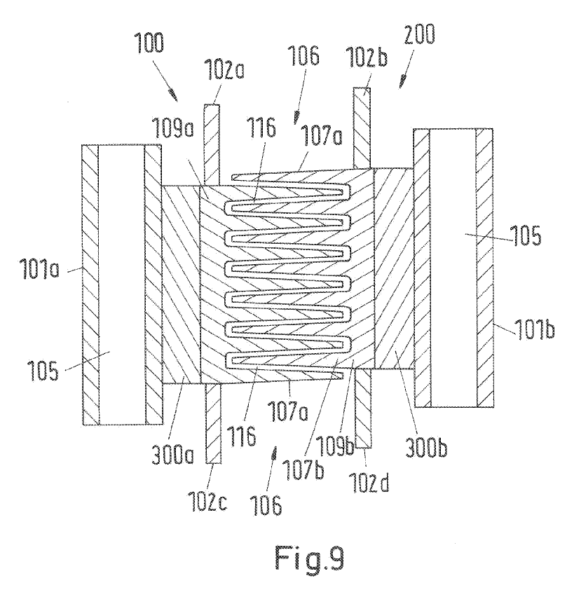

FIG. 9 a cross-section through the arrangement illustrated in FIG. 8 along the line IX-IX,

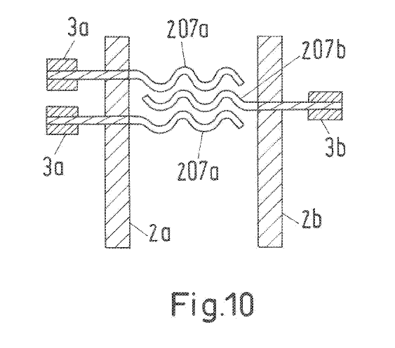

FIG. 10 a detail corresponding to the central region of the arrangement illustrated in FIG. 2 to illustrate a specific embodiment of the heat conducting body with wave shape, deviating from FIG. 2, and

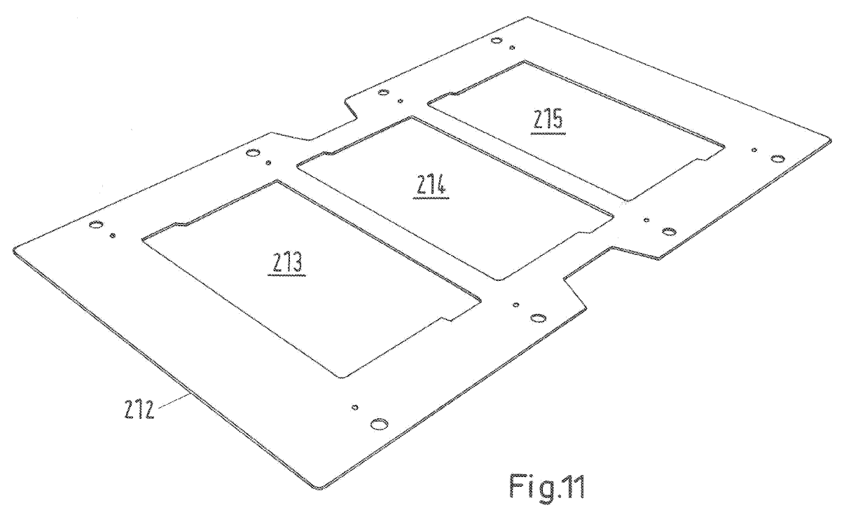

FIG. 11 a specific exemplary embodiment of a supporting structure illustrated in FIG. 4.

The arrangement illustrated in FIG. 1 and FIG. 2 has two heat sinks 1a, 1b, which each have a plurality of channels 5a, 5b for a cooling liquid flow. The channels 5, in the illustration of FIG. 1, run with their flow direction perpendicularly to the plane of the drawing, whereas in FIG. 2 they run with their flow direction from top to bottom or vice versa in the plane of the drawing. Outer surfaces of the heat sinks 5a, 5b not facing the channels 5 face towards one another. Areas in which strip-like thermoelectric elements 3a, 3b are arranged and in the middle between the heat sinks 5a, 5b an exhaust gas channel 6 are disposed between the heat sinks 5a, 5b. The flow direction for the exhaust gas of a combustion engine flowing through the exhaust gas channel 6 runs in FIG. 1 from bottom to top in the plane of the drawing and runs in FIG. 2 perpendicularly to the plane of the drawing towards the viewer.

In the exemplary embodiment illustrated in FIG. 1 and FIG. 2, fins 4a, 4b are formed as an integral part of the heat sinks 1a, 1b. There is thus no joining of fins and heat sink. Ten fins 4a, 4b extend in the exemplary embodiment from each of the heat sinks 1a, 1b in the direction of the exhaust gas channel 6. The fins 4a, 4b serve as a connection to the strip-like thermoelectric elements 3a, 3b. Two thermoelectric elements 3a, 3b are connected to each of the fins 4a, 4b, for example adhesively bonded or soldered, so that during operation of the arrangement excess heat is transferred from the thermoelectric elements 3a, 3b via the fins 4a, 4b to the inner wall of the heat sink 1a, 1b and from there is transferred to the cooling liquid within the channel 5a, 5b. The cooling liquid transports the excess heat away. In this way, the low-temperature side of the thermoelectric elements 3a, 3b connected to the fins 4a, 4b is held at a low temperature.

The strip-like thermoelectric elements, in the cross-section illustrated in FIG. 2, have a very much smaller cross-sectional area compared to the very much larger surface illustrated in FIG. 1. In particular, the material pairs of many thermoelectric elements can be arranged one above the other from top to bottom in the surface of the thermoelectric elements 3a, 3b illustrated in FIG. 1, as is already known per se from the prior art. The thermoelectric elements themselves are not illustrated in FIG. 1.

The thermoelectric elements 3a, 3b are connected in pairs to a fin-like heat conducting body 7a, 7b, for example again by adhesive bonding or soldering, on the high-temperature sides pointing towards the exhaust gas channel 6. The inner end regions of the thermoelectric elements 3a, 3b pointing towards the exhaust gas channel 6 enclose therebetween, in pairs, an end region of the heat conducting body 7a, 7b. The heat conducting body therefore mechanically stabilises the pairs of thermoelectric elements 3a, 3b in the same manner as the fins 4a, 4b.

The heat sinks 1a, 1b support the thermoelectric elements 3a, 3b via the fins 4a, 4b formed integrally on the heat sinks in the shown exemplary embodiment, and the thermoelectric elements in turn support the heat exchangers 7a, 7b. The total weight of the thermoelectric elements 3a, 3b and of the heat exchangers 7a, 7b is therefore supported by the heat sinks 1a, 1b.

A seal 2a, 2b made of flexible material, in the exemplary embodiment a nonwoven material formed of mineral fibres, runs close to the high-temperature side ends of the thermoelectric elements 3a, 3b. The heat exchangers 7a, 7b pass through the seal 2a, 2b, which is held by clamping forces and optionally by additional adhesive on the heat conducting bodies 7a, 7b. The heat conducting bodies 7a supported by the first heat sink 1a thus hold the seal 2a, and the second heat conducting bodies 7b supported by the second heat sink 1b hold the second seal 2b. The seals 2a, 2b are mat-like, i.e. they have two large-area surfaces, which are arranged on mutually opposed sides of the seal 2a, 2b. The outer of these surfaces faces towards the thermoelectric elements 3a, 3b and thus also the heat sink 1a, 1b, whereas the other of the large-area surfaces forms the wall of the exhaust gas channel 6.

Within the exhaust gas channel 6, the heat conducting bodies 7a, 7b, as has already been described, are interlaced with one another in a comb-like manner, that is to say in the cross-section of FIG. 2, in the order in the plane of the drawing from top to bottom, a first heat conducting body 7a, which extends from the left in the plane of the drawing into the exhaust gas channel 6, is followed by a heat conducting body 7b which extends from the right into the exhaust gas channel, etc. In accordance with the number of ten fins 4a, 4b in the exemplary embodiment and twenty strip-like thermoelectric elements 3a, 3b, ten first heat conducting bodies 7a and ten second heat conducting bodies 7b are provided. Compared to the overall flow cross-section of the exhaust gas channel 6, narrow flow channels 16 are formed in each case by a first heat conducting body and a second heat conducting body 7b. In total, nineteen narrow flow channels 16 of this type are formed in the exemplary embodiment. A further narrow or slightly wider flow channel can be formed at the top and at the bottom in FIG. 2 if there is a screen disposed there (not illustrated in FIG. 2), the inner, large-area surface of which faces towards the strip-like thermoelectric elements 3a, 3b and within the exhaust gas channel 6 faces towards the heat conducting bodies 7a, 7b. The seals 2a, 2b can be supported at the respective screen, so that they form the peripheral walls of the exhaust gas channel 6, jointly with the screens to be arranged at the top and bottom in the plane of the drawing of FIG. 2. The screens can therefore also be referred to as walls.

As can be clearly seen from FIG. 2, the seals 2a, 2b separate the exhaust gas channel 6 from an area in which, respectively, the first thermoelectric elements 3a (area 10) and the second thermoelectric elements 3b (area 20) are disposed. On account of the strip-like arrangement of the thermoelectric elements 3, the areas 10, 20 are divided into narrow sub-areas 9a, 9b. For example, the lowermost second thermoelectric elements 3b illustrated at the bottom on the right in FIG. 2 and denoted by the reference sign 8 delimit one of these sub-areas 9b. Optionally, the sub-areas 9a, 9b can be passed through by a flushing gas before, during and/or after operation of the arrangement, wherein the flow direction is parallel to the flow direction of the hot gas in the exhaust gas channel 6 and therefore runs for example perpendicularly to the plane of the drawing in FIG. 2.

FIG. 3 shows a basic unit with a heat sink 1, which for example can be the heat sink 1a, 1b from FIG. 1 and FIG. 2, if thermoelectric elements, fins and heat conducting bodies are disposed on either side of the heat sink 1a, 1b in the arrangement of FIG. 1 and FIG. 2. In this case, the illustrations in FIG. 1 and FIG. 2 would be merely partial illustrations and would not show the fins, thermoelectric elements and heat conducting bodies arranged on the outside of the heat sinks 1a, 1b.

Starting from the heat sink 1 in FIG. 3, fins 4, to which strip-like thermoelectric elements 3 are secured, extend on either side to the right and left in the illustration of FIG. 3. Heat conducting bodies 7 are connected to the thermoelectric elements 3, so that, in each case starting from the heat sink 1, the sequence of fins 4, thermoelectric element 3 and heat conducting body 7 extends away from the heat sink 1. In the exemplary embodiment illustrated in FIG. 3, sixteen arrangements of this kind extend on each side of the heat sink 1 and on the whole form lamella-like stacks, wherein the narrow flow channels 16 are formed between the heat conducting bodies 7 of the lamellas. Each individual one of the lamellas with a fin 4, a strip-like thermoelectric element 3, and a fin-like heat conducting body 7 can be formed in particular as has been described with reference to FIG. 1 and FIG. 2.

The seals which are to be arranged one on the left and one on the right of the heat sink 1 illustrated in FIG. 3 are not illustrated in FIG. 3. Furthermore, neither a further basic unit nor a housing wall, which are to be arranged to the left and right of the heat sink 1 illustrated in FIG. 3, is illustrated.

The heat sink 1 in FIG. 3 comprises eight liquid channels 5 running from the front on the right to the rear on the left, wherein the ends of most of these channels 5 are preferably closed, with the exception of at least one end used as inflow opening or outflow opening in order to introduce cooling liquid into the heat sink 1 or discharge it therefrom. The heat sink 1 also comprises two channels 15 running perpendicularly to the channels 5, with one of said two channels being arranged in the foreground of the image and the other being arranged in the background. These perpendicularly running channels 15 connect all channels 5 to one another, so that a distributor is formed on the inflow side and a collector is formed on the outflow side. The ends of the perpendicularly running cooling channels 15 are preferably closed.

FIG. 4 shows an arrangement with nine of the basic units illustrated in FIG. 3, wherein in each case three adjacently arranged basic units 14 are arranged in three levels one above the other. In each level the heat conducting bodies 7 of the basic unit arranged in the middle of the level are interlaced in a comb-like manner with the inwardly pointing heat conducting bodies of the basic unit arranged on the outside in the level. As already discernible in FIG. 3 at the bottom and at the top in the image, the heat sinks 1 each have a fastening protrusion at the front and at the rear and at the bottom and at the top. At the transition between the levels, a supporting structure 12 is situated in each case, which runs around the stack at the height level of the transition between the levels and at which the heat sinks 1 are secured via their fastening protrusions 13. Here, merely either the lower fastening protrusion 13 or the upper fastening protrusion 13 of the heat sink 1 is preferably fixedly connected to the supporting structure 12. The other fastening protrusion is preferably guided merely movably on the supporting structure 12. In this way, the basic units can move relative to the other basic units in the event of thermal expansion and contraction. However, it is possible alternatively that all fastening protrusions 13 are fixedly connected to the supporting structures 12 at the transitions between the levels, and the supporting structures 12 are movable relative to a housing (not illustrated in FIG. 4).

In any case, it is preferred that the lower fastening protrusions 13 of the lowermost level of basic units 14 are fixedly connected to a housing (not illustrated in FIG. 4), but not the upper fastening protrusions 13 of the upper level. Alternatively, the upper fastening protrusions 13 of the upper level could be fixedly connected to the housing, whereas the lower fastening protrusions 13 of the lower level are not fixedly connected to the housing. The fastening protrusions 13 not fixedly connected to the housing are preferably guided movably relative to the housing so as to enable a thermally induced expansion and contraction. In FIG. 5 a stack of three is arranged in succession in the flow direction (illustrated by arrows pointing from bottom to top). Each of the basic units comprises a heat sink 1 and thermoelectric elements 3 connected on opposite sides to the heat sink 1 and heat conducting bodies 7 connected to the thermoelectric elements. The length of the heat conducting bodies 7 in the direction away from the heat sink 1 into the interior of the gas channel (the delimitations of the gas channel by the seals are not illustrated in FIG. 5) varies, however, in the basic units. The basic unit 14a arranged at the front in the flow direction has the heat conducting bodies 7 with the shortest length. The middle basic unit 14b has the heat conducting bodies 7 with a slightly longer length, and the basic unit 14c at the end of the arrangement in the flow direction has the heat conducting bodies 7 with the longest length, which is slightly longer than the length of the heat conducting bodies 7 of the middle basic unit 14b. The reduction of the temperature of the hot gas flow is compensated on account of the different length and therefore the different size of the surfaces of the heat conducting bodies 7.

FIG. 5 also shows, for each of the basic units 14, a connection point 25 for introducing or removing the cooling liquid into/from the heat sink 1, that is to say the corresponding end of the cooling channel is open at the connection point 25.

FIG. 6 shows a thermoelectric generator with a stack of basic units as in FIG. 4, wherein however additional housing parts and connection points are illustrated. Apart from the screens 11 already presented in FIG. 4, which close off the lamella stacks to the front and rear and form the walls of the gas channels to the front and rear, lateral walls 18 of the gas channels arranged to the left and right in the illustration are also shown. At the bottom, an exhaust gas inlet 10 with funnel-shaped widening to a lower supporting frame 41 and an exhaust gas outlet 30 with a funnel-shaped tapering starting from an upper supporting frame 31 are also illustrated. The lower supporting frame 41 comprises three openings for admitting flushing gas into the areas separated by the seals. The upper supporting frame 31 has three outlet openings 32 for discharging the flushing gas. What are not illustrated in FIG. 6 are outer housing walls, which can connect at the bottom to the lower supporting frame 41 and at the top to the upper supporting frame 31 or can be guided through the respective frames.

Merely the lower supporting frame 41 is preferably fixedly connected to the stack of the basic units 14, whereas the upper supporting frame 31 merely limits the freedom of movement of the upper level of basic units 14 and enables a movement on account of thermal expansion and contraction. The cross-section through a heat sink 1 illustrated in FIG. 7, for example the heat sink of one of the basic units from FIG. 3 to FIG. 6, shows the liquid channels 5 running parallel to one another in the exemplary embodiment 8 and the two liquid channels 15 running perpendicularly thereto. What are not illustrated are the connections to the thermoelectric elements (likewise not illustrated), which in the illustration of FIG. 7 can be, or are arranged on the heat sink 1 in the foreground and in the background.

The second-lowest of the eight cooling liquid channels 5 running in parallel comprises an opening on the left in FIG. 7, which opening forms the inlet 25 for the cooling liquid. The second-uppermost of the eight cooling liquid channels 5 running in parallel has an opening illustrated on top right in FIG. 7, which opening forms the cooling liquid outlet 26. All other ends of the channels 5, 15 are closed, for example by stoppers. The use of stoppers makes it possible to produce the cooling liquid channels 5, 15 by drilling in a solid block. The fastening protrusions 13 are illustrated to the right and left, in each case at the top and bottom.

The arrangement illustrated in FIG. 8 and FIG. 9 has, as a variant to the arrangement illustrated in FIG. 1 and FIG. 2, block-like thermoelectric modules 300a, 300b. Similarly to FIG. 1 and FIG. 2, a heat sink 101a, 101b with a plurality of cooling liquid channels 105 running parallel to one another is illustrated on the right and left in the arrangement. A plurality of the block-like thermoelectric modules 300a, 300b is connected over the entire area to the heat sink 101 on the inwardly pointing flat surface of the heat sink 101, optionally in each case via a compensating element (not illustrated). A heat conducting body 109a, 109b is arranged on the inner side of the thermoelectric modules 300a, 300b respectively, which heat conducting bodies in the exemplary embodiment have fins 107a, 107b tapering in cross-section in their extent to their free ends. The protrusions 107 are interlaced with one another in a comb-like manner. A meandering intermediate space 116, which is part of the exhaust gas channel 106, is thus formed in the cross-section illustrated in FIG. 9.

The flow direction of the exhaust gas channel 106 runs in the illustration of FIG. 8 from bottom to top and in the illustration of FIG. 9 from rear to front perpendicularly to the plane of the drawing. A first seal is combined with the heat conducting body 109a and has two parts 102a, 102c. A second seal with parts 102b, 102d is combined with the second heat conducting body 109b. It can be seen in the illustration of FIG. 9 that the parts 102a, 102b are disposed on a side of the arrangement with the interlaced heat conducting bodies 109, and the parts 102c, 102d are disposed on the opposite side of the arrangement of the heat conducting bodies 109. Accordingly, in the illustration of FIG. 8, the end faces merely of the seal parts 102c, 102d can be seen. The first seal with the parts 102a, 102c separates the gas channel 106 from an area 100 disposed between the seal and the heat sink and in which the first thermoelectric modules 300a are disposed. Accordingly, the second seal with the parts 102b, 102d separates the gas channel 106 from an area 200 in which the second thermoelectric modules 300b are disposed. In this way, it is prevented that hot gas flowing in the gas channel 106 comes into direct contact with the thermoelectric module 300. As also in the case of the strip-like thermoelectric modules of the arrangement in FIG. 1 and FIG. 2, a higher temperature difference across the thermoelectric modules can therefore be achieved. Here, heat from the gas channel is introduced with high efficiency into the high-temperature side of the thermoelectric modules.

FIG. 10 shows a detail of a preferred variant of the arrangement illustrated in FIG. 2. The detail relates to the shaping of the heat conducting bodies in the local region formed by the exhaust gas channel and delimited by the seals 2a, 2b on opposite sides. Whereas the heat conducting bodies 7a, 7b in the embodiment illustrated in FIG. 2 are planar with a straight extent along the longitudinal axis (running from right to left and from left to right in FIG. 2), the heat conducting bodies 207a, 207b in the embodiment illustrated in FIG. 10 have an undulating extent in the longitudinal direction with wave crests and wave troughs. The wave crests and wave troughs run perpendicularly to the plane of the drawing of FIG. 10. Merely two first heat exchangers 207a and one second heat exchanger 207b are illustrated. The wave troughs and wave crests of the most closely adjacent first and second heat conducting bodies 207a, 207b run parallel to one another, so that the distance of the surfaces of the most closely adjacent heat conducting bodies 207 is constant or approximately constant in the extent of the heat conducting bodies 207 from the thermoelectric elements 3a, 3b to the free ends of the heat conducting bodies 207. The term ‘approximately constant’ is understood to mean that there is no change in the spacing in the aforementioned extent that can be attributed to an offset in the longitudinal direction or a different shape of the wave troughs and wave crests. However, a change in spacing in particular can be provided in practice because the undulating end portions of the heat conducting bodies 207 are unintentionally twisted.

Since FIG. 10 depicts a detail, merely the three aforementioned heat conducting bodies 207, a portion of each of the seals 200a, 200b, and merely the high-temperature side end regions of the thermoelectric elements 3a, 3b are illustrated, to which the three illustrated heat conducting bodies 207 are secured. In practice, further thermoelectric elements and heat conducting bodies are provided in the manner illustrated in FIG. 2, wherein, however, the heat conducting bodies likewise have undulating end portions.

The undulating interlaced arrangement of the end portions of the heat conducting bodies leads to an increased surface of the heat conducting bodies compared to the shaping in FIG. 2 and thus to an improved transfer of heat from the hot gas to the heat conducting bodies. The flow of the hot gas in the exhaust gas channel, however, preferably is not turbulent on account of the wave shape of the heat conducting bodies.

The surface of the end portions of the heat conducting bodies is increased based on the longitudinal portion, i.e. the quotient of the heat transfer coefficient and the length of the end portion in the longitudinal direction is greater. This makes it possible to choose the length of the end portion to be smaller and still attain a good transfer of heat from the hot gas to the heat conducting bodies. If the flow of the hot gas through the gas channel is not turbulent, the flow resistance is merely slightly higher than in the case of the straight embodiment of the end portions of the heat conducting bodies in FIG. 2.

FIG. 11 shows a supporting structure 212 similar to that in FIG. 4, which can be arranged in the flow direction of the hot gas between two levels of basic units arranged in succession so as to support at least the basic units of one of the two levels on the supporting structure 212. The supporting structure 212 is made in particular from a metal sheet and has three (with the exception of additional depressions) approximately rectangular cutouts 213, 214, 215 for one of the levels, the levels, or for a transition of the levels. In the perspective illustration of FIG. 11, the flow direction for the hot gas runs from bottom to top.

1. A thermoelectric generator for converting heat of a hot gas flow into electric energy, wherein the thermoelectric generator comprises:
at least one thermoelectric module with a plurality of thermoelectric elements,
a gas channel on a high-temperature side of the thermoelectric module for conducting the hot gas flow in a flow direction of the gas channel,
a heat sink for cooling the thermoelectric module, wherein the heat sink is in contact with the thermoelectric module on a low-temperature side of the thermoelectric module, and
at least one heat conducting body which extends into the gas channel in a direction running transversely to the flow direction on the high-temperature side of the thermoelectric module and which has a free end within the gas channel, wherein the heat conducting body is part of the thermoelectric module or is connected to the thermoelectric module on the high-temperature side of the thermoelectric module,
wherein the thermoelectric generator has a seal which separates an area arranged between the heat sink and the gas channel from the gas channel and seals the area from the hot gas flow flowing in the gas channel during the operation of the thermoelectric generator.

2. The thermoelectric generator according to claim 1, wherein the seal is made of a flexible material.

3. The thermoelectric generator according to claim 2, wherein the flexible material is designed to deform under the action of external forces.

4. The thermoelectric generator according to claim 1, wherein the material of the seal comprises a nonwoven or woven material formed of fibres.

5. The thermoelectric generator according to claim 1, wherein the seal is passed through at least at one point by the heat conducting body or one of the heat conducting bodies or by the thermoelectric module and/or parts of the seal are separated from one another at least at one point by the heat conducting body or one of the heat conducting bodies or by the thermoelectric module.

6. The thermoelectric generator according to claim 1, wherein protrusions formed by the heat conducting body or by a plurality of the heat conducting bodies and extending into the gas channel are formed as fins of a heat exchanger for transferring the heat of the hot gas flow to the thermoelectric module.

7. The thermoelectric generator according to claim 1, wherein the seal extends from the heat conducting body or from one of the heat conducting bodies to a gas channel wall or to a supporting part of the thermoelectric generator, but is not connected to the gas channel wall or the supporting part of the thermoelectric generator.

8. The thermoelectric generator according to claim 1, wherein the thermoelectric elements each comprise a pair of different materials, which are in contact with one another in a first contact region on the low-temperature side and are in contact with one another in a second contact region on the high-temperature side, so that an electrical voltage is produced between the first and the second contact region on account of a higher temperature in the second contact region than in the first contact region, and wherein the first contact region is disposed in the area separated by the seal from the gas channel.

9. The thermoelectric generator according to claim 1, wherein the area separated by the seal from the gas channel has, separately from the gas channel, an inlet and an outlet through which a flushing gas for flushing the area can be admitted and discharged before, during and/or after an operation of the thermoelectric generator.

10. The thermoelectric generator according to claim 1, wherein the heat sink is connected to a part supporting the weight of the thermoelectric generator and is supported by the supporting part, and wherein the heat sink supports the thermoelectric module.

11. A rail vehicle comprising a thermoelectric generator according to claim 1, wherein the rail vehicle comprises an engine and the thermoelectric generator is arranged in an exhaust gas tract of the engine or is thermally coupled to the exhaust gas tract.

12. A method for producing a thermoelectric generator for converting heat of a hot gas flow into electrical energy, comprising the following steps:
providing at least one thermoelectric module with a plurality of thermoelectric elements,
providing a gas channel for guiding the hot gas flow in a flow direction of the gas channel on a high-temperature side of the thermoelectric module,
arranging a heat sink for cooling the thermoelectric module on a low-temperature side of the thermoelectric module,
coupling the heat sink to the thermoelectric module on the low-temperature side, and
arranging at least one heat conducting body on the high-temperature side of the thermoelectric module, so that the heat conducting body extends into the gas channel in a direction transverse to the flow direction and has a free end within the gas channel, wherein the heat conducting body is part of the thermoelectric module or is connected to the thermoelectric module on the high-temperature side of the thermoelectric module,
wherein a seal is arranged so that it separates an area arranged between the heat sink and the gas channel from the gas channel and, during operation of the thermoelectric generator, seals the area with respect to the hot gas flow flowing in the gas channel.
